(19) United States
(12) Patent Application Publication
(10) Pub. No.: US 2026/0176760 A1
(43) Pub. Date: Jun. 25, 2026

(54) METHOD AND APPARATUS FOR DEPOSITING SILICON-CONTAINING LAYER

(71) Applicant: ASM IP Holding B.V., Almere (NL)

(72) Inventors: KiHun Kim, Yongin-si (KR); Makoto Igarashi, Tokyo (JP); SangHeon Yong, Yongin-si (KR); Sungha Choi, Suwon-si (KR); JuHyuk Park, Hwaseong-si (KR); Jihye Yang, Ansan-si (KR); Gaurav Pathak, Chandler, AZ (US); Agung Setiadi, Tokyo (JP)

(21) Appl. No.: 19/424,395

(22) Filed: Dec. 18, 2025

Related U.S. Application Data
(60) Provisional application No. 63/738,075, filed on Dec. 23, 2024.

(51) Int. Cl. C23C 16/455; C23C 16/04; H10P 14/60; H10P 14/69

(52) U.S. Cl. CPC C23C 16/45553; C23C 16/045; C23C 16/4554; H10P 14/6336; H10P 14/6339; H10P 14/6903

(57) ABSTRACT

A method and apparatus for filling a gap with a material comprising silicon are disclosed. The method comprises providing a substrate into a reaction chamber, wherein the substrate comprises at least one gap; providing a first reactive species generated from a capacitively-coupled plasma produced from a first reactant gas into the reaction chamber; and executing a plurality of deposition cycles. The deposition cycle comprises providing a first silicon precursor in vapor phase into the reaction chamber; and providing a second reactive species generated from an inductively-coupled plasma produced from a second reactant gas into the reaction chamber.

### CROSS-REFERENCE TO RELATED APPLICATIONS

This application claims priority to U.S. Provisional Patent Application Ser. No. 63/738,075 filed Dec. 23, 2024 titled METHOD AND APPARATUS FOR DEPOSITING SILICON-CONTAINING LAYER, the disclosure of which is hereby incorporated by reference in its entirety.

### FIELD OF INVENTION

The present disclosure generally relates to methods and apparatus for manufacturing electronic devices. More particularly, the disclosure relates to methods and apparatus for depositing films during the formation of the electronic devices.

### BACKGROUND OF THE DISCLOSURE

During manufacturing of electronic devices, such as integrated circuits, films or layers of material are often deposited onto a surface of a substrate. Such films can be patterned and etched to form desired structures. Additionally, or alternatively, films can be deposited to fill gaps or recesses, such as vias, trenches, or spaces between fins, on a surface of a substrate.

In the case of filling a gap, a typical film deposition process may be subjected to drawbacks, including void formation in the gap. Voids may be formed when the deposited material forms a constriction near a top of the gap before the gap is completely filled with the deposited material. Such voids may compromise device isolation of the devices of an integrated circuit (IC) as well as the overall structural integrity of the IC. Unfortunately, preventing void formation during gap fill may place size constraints on the gaps, which may limit device packing density of the IC.

Void formation may be mitigated by decreasing gap depth and/or tapering gap sidewalls, so that the openings of the gap are wider at the top than at the bottom of the gap. A trade off in decreasing the gap depth may be reducing the effectiveness of the device isolation, while the larger top openings of gaps with tapering sidewalls may use up additional IC real estate. Such problems can become increasingly problematic when attempting to reduce device dimensions. Furthermore, it may be generally desirable to form films of relatively high quality—e.g., films having relatively high etch rates in, for example, hydrofluoric and/or phosphoric acid. Accordingly, improved methods and apparatus for forming high-quality films and/or for filling a gap are desired.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to method of filling a gap performing a deposition process and to apparatus for depositing the material for filling the gap. While the ways in which various embodiments of the present disclosure address drawbacks of prior methods are discussed in more detail below, in general, exemplary embodiments of the disclosure provide improved methods and apparatus for depositing high quality material and/or to methods for seamlessly filling high aspect ratio gaps with the deposited material. As set forth in more detail below, exemplary methods can include a step of treating a surface of a substrate to inhibit or slow a growth rate of the deposited material. The growth-rate inhibition is thought to improve a quality of the deposited material and/or to facilitate seamless filling of a gap with the deposited material. Additionally, high-quality material can be deposited, without post-treatment annealing of the deposited material that is otherwise often performed to improve the quality of the deposited material.

In accordance with at least one embodiment of the disclosure, a method for filling a with a material comprising silicon is provided. The method comprises providing a substrate into a reaction chamber, wherein the substrate comprises at least one gap; providing a first reactive species generated from a capacitively-coupled plasma produced from a first reactant gas into the reaction chamber; and executing a plurality of deposition cycles. The deposition cycle comprises providing a first silicon precursor in vapor phase into the reaction chamber; and providing a second reactive species generated from an inductively-coupled plasma produced from a second reactant gas into the reaction chamber.

In some embodiments, the method further comprises providing a second silicon precursor in vapor phase into the reaction chamber before providing the first reactive species into the reaction chamber.

In some embodiments, the first silicon precursor and second silicon precursor are the same. In some embodiments, the first silicon precursor and second silicon precursor are different. In some embodiments, the first silicon precursor and the second silicon precursor comprise an aminosilane. In some embodiments, the first silicon precursor and the second precursor is selected from the list consisting of diethylaminosilane, bis(diethylamino)silane, diisopropylaminosilane, bis(dimethylamino)silane, hexaethylaminodisilane, tetraethylaminosilane, bis(tert-butylamino)silane, bis(triethylsilyl)amine, trimethylaminosilane, trimethylsilyldiethylamine, tris(dimethylamino)silane, bis(ethylmethylamino)silane, tetraethyl orthosilicate, silicon tetrachloride, hexachlorosilane, and bis(dimethylamino)dimethylsilane.

In some embodiments, the first reactant gas is nitrogen gas which forms an inhibition layer in a vicinity of a top of the gap, and wherein the reaction of the first silicon precursor in the vicinity of the top of the gap is at least partially inhibited by the inhibition layer.

In some embodiments, the steps of providing a first reactive species into the reaction chamber, providing a first silicon precursor in vapor phase into the reaction chamber; and providing a second reactive species into the reaction chamber are performed cyclically, and wherein a ratio of a number of steps of forming first reactive species and a number of deposition cycles ranges from about 1:1 to about 1:10.

In some embodiments, the first reactant gas is oxygen-containing gas.

In some embodiments, the steps of providing a second silicon precursor in vapor phase into the reaction chamber and providing the first reactive species into the reaction chamber are performed cyclically to deposit a first silicon-containing layer into the gap.

In some embodiments, the steps of providing a first silicon precursor in vapor phase into the reaction chamber and providing the second reactive species into the reaction chamber are performed cyclically to deposit a second silicon-containing layer into the gap.

In some embodiments, the second silicon-containing layer is deposited on top of the first silicon-containing layer.

In some embodiments, the deposition cycle of the second silicon-containing layer is not performed until a desired thickness of the first silicon-containing layer is deposited.

In some embodiments, the first silicon-containing layer is a liner layer.

In some embodiments, the second silicon-containing layer is used to fill the gap on the substrate.

In some embodiments, the capacitively-coupled plasma is produced in pulse. In some embodiments, the inductively-coupled plasma is produced in pulse.

According to a further aspect of the invention there is provided a semiconductor processing apparatus. The apparatus comprises one or more reaction chambers for accommodating a substrate comprising a gap; a first source for a first reactant in gas communication via a first valve with one of the reaction chambers; a second source for a second reactant in gas communication via a second valve with one of the reaction chambers; a third source for a first silicon precursor in gas communication via a third valve with one of the reaction chambers; a capacitively-coupled plasma source connected to at least one of the reaction chambers; a inductively-coupled plasma source connected to at least one of the reaction chambers; and a controller operably connected to the first, second, and third gas valves. The controller is configured and programmed to control: providing a first reactive species generated from a capacitively-coupled plasma produced from a first reactant gas into the reaction chamber; executing a plurality of deposition cycles, wherein the deposition cycle comprises providing a first silicon precursor in vapor phase into the reaction chamber; and providing a second reactive species generated from an inductively-coupled plasma produced from a second reactant gas into the reaction chamber.

In some embodiments, the semiconductor processing apparatus further comprises a fourth source for a second silicon precursor in gas communication via a fourth valve with one of the reaction chambers, and wherein the controller is further operably connected to the fourth gas valve and configured and programmed to control providing a second silicon precursor in vapor phase into the reaction chamber before providing the first reactive species into the reaction chamber.

In some embodiments, the capacitively-coupled plasma source, and the inductively-coupled plasma source are connected to the same reaction chamber.

In some embodiments, the capacitively-coupled plasma source is connected to a substrate support supporting the substrate in the reaction chamber.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein. These and other embodiments will become readily apparent to those skilled in the art from the following detailed description of certain embodiments having reference to the figures, the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrated a method for depositing a material in a gap in accordance with at least one embodiment of the disclosure.

FIG. 2 illustrated a method for depositing a material in a gap in accordance with at least one embodiment of the disclosure.

FIG. 3 illustrates schematic representation of an apparatus suitable for filling a gap in accordance with at least one embodiment of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

Exemplary embodiments of the disclosure can be used to deposit material on a surface of a substrate. For example, exemplary methods and apparatus can be used to fill gaps, such as trenches, vias, and/or areas between fins, on a surface of a substrate.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

By way of examples, a substrate can include a material that includes hydrogen and/or hydroxyl group terminated sites. For example, the substrate can be or include silicon and/or silicon oxide with hydroxyl terminated groups and/or hydrogen terminated groups.

As used herein, the term “comprising” indicates that certain features are included, but that it does not exclude the presence of other features, as long as they do not render the claim or embodiment unworkable. In some embodiments, the term “comprising” includes “consisting”. As used herein, the term “consisting” indicates that no further features are present in the apparatus/method/product apart from the ones following said wording. When the term “consisting” is used referring to a chemical compound or substance, it indicates that the chemical compound only contains the components which are listed.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

The term “essentially” as applied to a composition, a method, or a system generally means that the additional components do not substantially modify the properties and/or function of the composition, the method, or the system.

As used herein, the term “reactant” or “precursor” can be used interchangeably and refer generally to at least one compound that participates in deposition reaction to deposit a layer on a substrate.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate/and/or embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include noble gasses such as helium, argon, and any combination thereof. In some cases, an inert gas can include nitrogen and/or hydrogen. Purge gasses can comprise inert gasses.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X1-Xn, Y1-Ym, and Z1-Zo, the phrase is intended to refer to a single element selected from X, Y, and Z, a combination of elements selected from the same class (e.g., X1 and X2) as well as a combination of elements selected from two or more classes (e.g., Y1 and Zo).

In this specification, a “process” may refer to a series of one or more steps, leading to an end result. Additionally, a “step” may refer to a measure taken in order to achieve one or more pre-defined end results. Generally, a process may be a single-step or a multistep process. Additionally, a process may be divisible to a plurality of sub-processes, wherein individual sub-processes of such plurality of sub-processes may or may not share common steps.

In this specification, “active species” may refer to unstable molecular entities formed in plasma. Additionally or alternatively, active species may refer to ions and/or (free) radicals. Herein, an “ion” may refer to an atomic or molecular particle possessing a net electric charge, and/or a “radical” may refer to an atomic or molecular particle possessing an unpaired electron.

Herein, “plasma” may refer at least partially ionized gas containing various types of particles, e.g., electrons, atoms, ions, molecules, and/or radicals. Typically, plasma may be electrically neutral as a whole.

In this specification, a “direct plasma generator” may refer to an active species generator configured to form and sustain plasma within a process chamber between a perforated faceplate of a showerhead injector of said process chamber and a substrate support of said process chamber, whereas an “indirect plasma generator” may refer to an active species generator configured to form and sustain plasma within a process chamber such that a perforated faceplate of a showerhead injector of said process chamber and/or a mesh plate suitable for or configured to block ions is arranged between said plasma and a substrate support of said process chamber. Further, a “remote plasma generator” may refer to an active species generator configured to form and sustain plasma outside of a process chamber and to introduce active species, e.g., radicals, formed in said plasma into said process chamber, for example, via an active species duct or channel.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential exposure of a substrate to precursors (and/or reactants) into a reaction chamber, and exposure of a substrate to plasma generated species to deposit a layer over the substrate and includes processing techniques such as plasma-enhanced atomic layer deposition (PEALD).

The term “plasma-enhanced atomic layer deposition” can refer to a deposition process in which deposition cycles, typically a plurality of consecutive deposition cycles, are conducted in a process chamber.

Generally, for a PEALD processes, during each cycle, a precursor is introduced to a reaction chamber and is chemisorbed to a deposition surface (e.g., a substrate surface that can include a previously deposited material from a previous PEALD cycle or other material) and forming about a monolayer or sub-monolayer of material that does not readily react with additional precursor (i.e., a self-limiting reaction). Thereafter, the substrate is exposed to a plasma-generated species which can be generated using any plasma, such as a direct, indirect, or remote plasma. Plasmas can be generated capacitively, inductively, using microwave radiation, or through other means. The plasma-generated species converts the chemisorbed precursor to the desired material on the deposition surface. Purging steps can be utilized during one or more cycles, e.g., after each step or pulse of each cycle, to remove any excess precursor from the process chamber and/or remove any excess plasma-generated species and/or reaction byproducts from the reaction chamber.

As used herein, the term “purge” may refer to a procedure in which a purge gas is provided to a reaction chamber in between a precursor pulse and a plasma pulse. It shall be understood that during a purge, the substrate is not exposed to plasma-generated species. For example, when a direct plasma is used, the plasma can be turned off during a purge. For example, a purge, e.g. using a purge gas such as nitrogen or a noble gas, may be provided between a precursor pulse and a reactant pulse, thus avoiding or at least minimizing gas phase interactions between the precursor and the reactant. It shall be understood that a purge can be effected either in time or in space, or both. For example, in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. As used herein, “silicon oxide” or “SiOx” refers to a material that includes silicon and oxygen. Silicon oxide can be represented by the formula SiOx, where x can be between 0 and 2. In some embodiments, silicon oxide may not include significant proportions of elements other than silicon and oxygen. Silicon oxide may be represented by the formula SiO2. In some embodiments, the silicon oxide comprises SiO2. In some embodiments, the silicon oxide may consist essentially of SiO2. In some cases, the silicon oxide may not include stoichiometric silicon oxide. In some cases, the silicon oxide can include other elements, such as carbon, nitrogen, and/or hydrogen.

As used herein, an “ion trap” refers to a structure, region, device, or configuration within a semiconductor processing chamber, such as a plasma-enhanced atomic layer deposition (PE-ALD) or radical-enhanced atomic layer deposition (RE-ALD) chamber, that is designed to selectively capture, retain, and control ionic species generated during deposition processes. The ion trap may be integrated into or positioned adjacent to the interior surfaces of the chamber, including, for example, chamber walls, gas distribution plates, or other internal components, to manage the energy, directionality, and concentration of ions within the reaction space. By influencing ion trajectories and reducing undesirable ion bombardment or plasma-induced damage to substrates and underlying device structures, the ion trap can help maintain optimal conditions for uniform and conformal film growth. The ion trap may be formed from various conductive, semiconductive, or dielectric materials, and can include engineered geometries, patterned surfaces, coatings, or other configurations tailored to the specific process chemistries, power levels, and plasma conditions of interest. In certain embodiments, the ion trap may be dynamically adjusted or tuned to accommodate changing process parameters, thereby improving process stability, film quality, and overall device performance in advanced semiconductor fabrication environments.

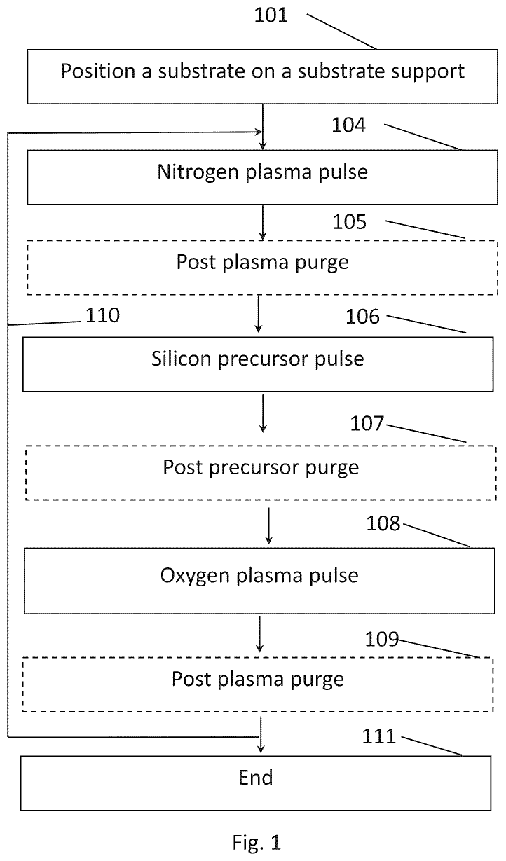

Now turning to the figures, FIG. 1 shows a schematic representation of an embodiment of a method as described herein. Method of depositing a material on a surface of a substrate can be used to, for example, fill one or more gaps, sometimes referred to as recesses or features, created during manufacturing of a structure—e.g., structures formed during the manufacture of electronic devices. An opening at a top of a gap may be, for example, less than 40 or even 20 nm wide; a depth of the gap may be more than 40, 100, 200 or even 400 nm. An aspect ratio of the gaps can range from, for example, about 5:1 to about 30:1. The deposited material may comprise silicon. In some embodiments, the deposited material is selected from silicon oxide, silicon nitride, silicon oxynitride and silicon oxycarbide.

Method of depositing a material into a gap on a surface of a substrate can be a cyclic deposition process, such as a plasma-enhanced ALD process. In the illustrated example, method of depositing a material on a surface of a substrate includes the steps of providing the substrate in a reaction chamber (101), providing a nitrogen plasma pulse into the reaction chamber (104), an optional post plasma purge (105), providing a silicon precursor into the reaction chamber (106), an optional post precursor purge (107), providing oxygen plasma into the reaction chamber (108) and an optional post plasma purge (109). As illustrated, steps 104-109 can be repeated a number of times, as illustrated by loop 110, prior to ending 111 method of depositing a material on a surface of a substrate.

Also, in some embodiments, the step of providing a nitrogen plasma pulse 104 does not performed during each cycle. In some embodiments, the ratio of a number of steps of providing a nitrogen plasma pulse and a number of deposition cycles (steps 106-109) ranges from about 1:1 to about 1:10.

Providing the substrate in a reaction chamber step 101 includes providing a substrate to a reaction chamber for processing in accordance with method. By way of example, a substrate can include a layer of or a layer including silicon and having at least one gap formed therein. Additionally or alternatively, the substrate can include a layer of, for example, silicon oxide or photoresist.

During step 101, the substrate can be brought to a desired temperature for subsequent processing using, for example, a substrate heater and/or radiative or other heaters. A temperature during steps 101-109 can be less than 600° C. or less than 550° C., or less than 500° C. or 450° C. or less than 400° C., or range from about 20° C. to about 600° C. or about 50° C. to about 550° C. A pressure within the reaction chamber during steps 101-109 can be from about 1 Torr to about 25 Torr or about 2 Torr to about 20 Torr.

During step 104, a first active species from a first reactant is formed. The first reactive species can be used to modify a surface of a substrate—e.g., to slow a growth rate of a material deposited during steps 106-109. For example, the first active species can be used to passivate otherwise active/reactive sites on the surface of a substrate. As a result, a growth per cycle of deposited material on the surface of the substrate (e.g., a surface of a gap formed within the substrate) can be reduced, compared to a growth per cycle of deposited material on a surface (e.g., another portion of the surface or another substrate surface) that has not been treated.

The active species can be formed in step 104 by using an in-situ plasma, such as capacitively-coupled plasma. A plasma power during step 104 can range from about 50 W to about 1500 W or about 150 W to about 1000 W or about 400 W to about 900 W. The plasma can be formed using an on time for the plasma during step 104 can range from about 1 seconds to about 60 (e.g., 10) seconds or about 1 seconds to about 40 (e.g., 5) seconds or about 8 seconds to about 12 seconds or about 3 seconds to about 7 seconds.

In some embodiments, the plasma is produced in pulse. For example, a plasma pulse period is between about 0.01 and 0.2 msec and the plasma pulse periods add up to the total plasma on time described above. A frequency of the pulsed plasma power can be between about 50 and 40,000 Hz or about 100 and 30,000 Hz.

In accordance with examples of the disclosure, the first reactant can comprise nitrogen or a gas comprising nitrogen. In accordance with further examples, the first reactant can include one or more of nitrogen, N₂/H₂, NH₃, NF₃, NO, N₂O, NO₂ and N₂H₄, or derivatives thereof.

Optionally, step 104 is followed by a post plasma purge step 105. During the purge step, excess reactant(s) and reaction byproducts, if any, may be removed from the reaction space/substrate surface, for example, by a purging gas pulse and/or vacuum generated by a pumping system. In some embodiments, the purging gas can be any inert gas, such as, without limitation, argon (Ar), nitrogen (N₂) and/or helium (He). A phase is generally considered to immediately follow another phase if a purge (i.e., purging gas pulse) or other reactant removal step intervenes. A flowrate of a purge gas during the purge sub step can range from about 500 sccm to about 5000 sccm or about 1000 sccm to about 4000 sccm. A time of the gas flow during the purge sub step can be relatively short to facilitate relatively rapid deposition of material. By way of examples, a time of the gas flow during this purge sub step can be greater than 0 and less than 1 second or range from about 0.1 seconds to about 0.9 seconds or about 0.3 seconds to about 0.5 seconds. In some embodiments, the purge is performed by forming a vacuum into the reaction chamber. In other words, the reactant is pumped away from the reaction chamber so that the reaction chamber is free, or substantially free from the reactant.

Steps 106-109 include performing a deposition cycle, such as a plasma-enhanced ALD deposition cycle. Each cycle can include introducing a silicon precursor into the reaction chamber 106, an optional post precursor purge 107, providing an active species from a reactant into the reaction chamber 108 and an optional post plasma purge 109. The silicon precursor reacts with the surface of the substrate to form chemisorbed layer in the gap, and the active species from a reactant reacts with the chemisorbed layer to form a deposited layer.

The silicon precursor of step 106 may comprise silane amines (aminosilanes), siloxane amines and silazane amines. In some embodiments, the silicon precursor is selected from the list consisting of diethylaminosilane, bis(diethylamino)silane, diisopropylaminosilane, bis(dimethylamino)silane, hexaethylaminodisilane, tetraethylaminosilane, bis(tert-butylamino)silane, bis(triethylsilyl)amine, trimethylaminosilane, trimethylsilyldiethylamine, tris(dimethylamino)silane, bis(ethylmethylamino)silane, tetraethyl orthosilicate, silicon tetrachloride, hexachlorosilane, and bis(dimethylamino)dimethylsilane.

A pulse/flow time to introduce the silicon precursor to the reaction chamber can range from, for example, about greater than 0 to less than 1 second or about 0.1 to 0.5 (e.g., 0.2) seconds, or about 1 seconds.

The active species can be formed in step 108 by using a remote plasma, such as inductively-coupled plasma. In step 108 the plasma is generated at a remote plasma unit and mainly radicals reach the surface of the substrate. A plasma power during step 108 can range from about 100 W to about 10000 W or about 150 W to about 7000 W or about 1000 W to about 10000 W. The plasma can be formed using an on time for the plasma during step 108 can range from about 1 seconds to about 20 (e.g., 10) seconds or about 1 seconds to about 15 (e.g., 5) seconds or about 8 seconds to about 12 seconds or about 3 seconds to about 7 seconds.

In some embodiments, the remote plasma is produced in pulse. For example, a plasma pulse period is between about 0.01 and 0.2 msec and the plasma pulse periods add up to the total plasma on time described above.

In accordance with examples of the disclosure, the second reactant can comprise oxygen or a gas comprising oxygen. In accordance with further examples, the first reactant can include one or more of oxygen, H₂O, H₂O₂, NO, N₂O, NO₂ and O₃, or derivatives thereof.

The post precursor purge 107 and post plasma purge 109 are similar to the post plasma purge 105 described above. The purging sub steps under step 107 and 109 may be particularly desirable to mitigate any unwanted CVD reactions that might otherwise occur.

In some embodiments, the steps can be performed in a different order. For example, in some embodiments, steps 106-109 can be performed before steps 104-105. This way a deposited layer is formed by using an inductively-coupled plasma and then it is treated with a capacitively-coupled plasma to densify the layer.

Once the gap is filled by a sufficient amount of cycles 110, the process ends 111.

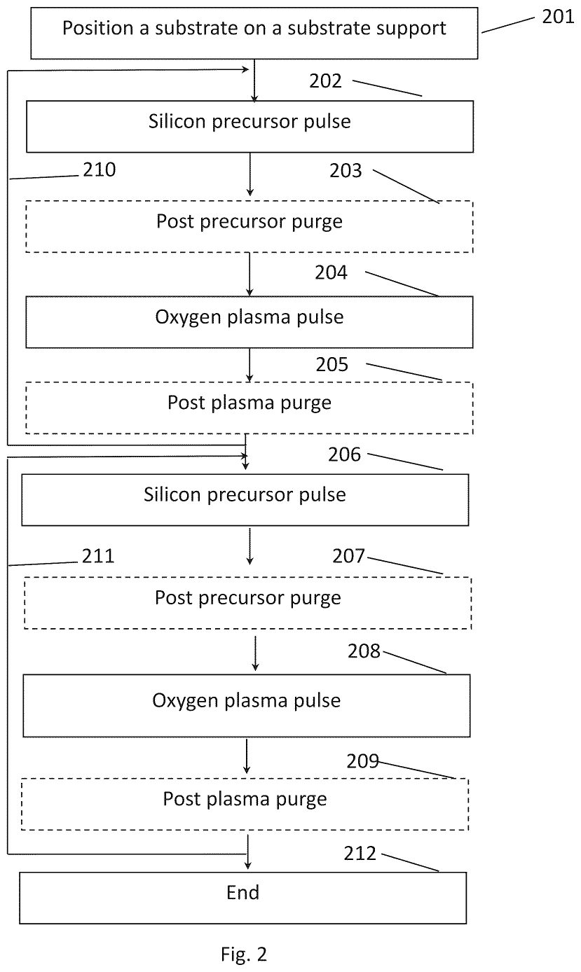

FIG. 2 shows a schematic representation of another embodiment of a method as described herein. Method of depositing a material on a surface of a substrate can be used to, for example, fill one or more gaps, sometimes referred to as recesses or features, created during manufacturing of a structure—e.g., structures formed during the manufacture of electronic devices. An opening at a top of a gap may be, for example, less than 40 or even 20 nm wide; a depth of the gap may be more than 40, 100, 200 or even 400 nm. An aspect ratio of the gaps can range from, for example, about 5:1 to about 30:1.

Method of depositing a material into a gap on a surface of a substrate can be a cyclic deposition process, such as a plasma-enhanced ALD process. In the illustrated example, method of depositing a material on a surface of a substrate includes the steps of providing the substrate in a reaction chamber (201), providing a first silicon precursor into the reaction chamber (202), an optional post precursor purge (203), providing an oxygen plasma pulse into the reaction chamber (204), an optional post plasma purge (205), providing a second silicon precursor into the reaction chamber (206), an optional post precursor purge (207), providing oxygen plasma into the reaction chamber (208) and an optional post plasma purge (209). As illustrated, steps 202-205 can be repeated a number of times, as illustrated by loop 210, and steps 206-209 can be repeated a number of times, as illustrated by loop 211, prior to ending 212 method of depositing a material on a surface of a substrate.

Providing the substrate in a reaction chamber step 201 includes providing a substrate to a reaction chamber for processing in accordance with method. By way of example, a substrate can include a layer of or a layer including silicon and having at least one gap formed therein. Additionally or alternatively, the substrate can include a layer of, for example, silicon oxide or photoresist.

During step 201, the substrate can be brought to a desired temperature for subsequent processing using, for example, a substrate heater and/or radiative or other heaters. A temperature during steps 201-209 can be less than 600° C. or less than 550° C., or less than 500° C. or 450° C. or less than 400° C., or range from about 20° C. to about 600° C. or about 50° C. to about 550° C. A pressure within the reaction chamber during steps 101-109 can be from about 1 Torr to about 5 Torr or about 2 Torr to about 4 Torr.

Steps 202-205 include performing a deposition cycle, such as a plasma-enhanced ALD deposition cycle. Each deposition cycle can include introducing a first silicon precursor into the reaction chamber 202, an optional post precursor purge 203, providing a first active species from a reactant into the reaction chamber 204 and an optional post plasma purge 205. The silicon precursor reacts with the surface of the substrate to form chemisorbed layer in the gap, and the active species from a reactant reacts with the chemisorbed layer to form a first deposited layer. The deposited layer may comprise silicon oxide, such as SiO₂. The first deposited layer may comprise a liner layer to protect and reduce oxidation of the underlying substrate. In some embodiments, the deposited layer may comprise silicon nitride. In some embodiments, the deposited layer may comprise silicon oxynitride. In some embodiments, the deposited layer may comprise silicon oxycarbide.

The first silicon precursor of step 202 may comprise silane amines (aminosilanes), siloxane amines and silazane amines. In some embodiments, the silicon precursor is selected from the list consisting of diethylaminosilane, bis(diethylamino)silane, diisopropylaminosilane, bis(dimethylamino)silane, hexaethylaminodisilane, tetraethylaminosilane, bis(tert-butylamino)silane, bis(triethylsilyl)amine, trimethylaminosilane, trimethylsilyldiethylamine, tris(dimethylamino)silane, bis(ethylmethylamino)silane, tetraethyl orthosilicate, silicon tetrachloride, hexachlorosilane, and bis(dimethylamino)dimethylsilane.

A pulse/flow time to introduce the silicon precursor to the reaction chamber can range from, for example, about greater than 0 to less than 3 second or about 0.1 to 2 (e.g., 0.5) seconds, or about 1 seconds.

Optionally, step 202 is followed by a post precursor purge step 203. During the purge step, excess reactant(s) and reaction byproducts, if any, may be removed from the reaction space/substrate surface, for example, by a purging gas pulse and/or vacuum generated by a pumping system. In some embodiments, the purging gas can be any inert gas, such as, without limitation, argon (Ar), nitrogen (N₂) and/or helium (He). A phase is generally considered to immediately follow another phase if a purge (i.e., purging gas pulse) or other reactant removal step intervenes. A flowrate of a purge gas during the purge sub step can range from about 500 sccm to about 5000 sccm or about 1000 sccm to about 4000 sccm. A time of the gas flow during the purge sub step can be relatively short to facilitate relatively rapid deposition of material. By way of examples, a time of the gas flow during this purge sub step can be greater than 0 and less than 2 second or range from about 0.5 seconds to about 1.5 seconds or about 0.3 seconds to about 1 seconds. In some embodiments, the purge is performed by forming a vacuum into the reaction chamber. In other words, the reactant is pumped away from the reaction chamber so that the reaction chamber is free, or substantially free from the reactant.

During step 204, a first active species from a first reactant is formed. The active species can be formed in step 204 by using an in-situ plasma, such as capacitively-coupled plasma. A plasma power during step 204 can range from about 50 W to about 1500 W or about 150 W to about 1000 W or about 400 W to about 900 W. The plasma can be formed using a pulse time of and/or an on time for the plasma during step 204 can range from about 0.2 seconds to about 20 (e.g., 10) seconds or about 1 seconds to about 10 (e.g., 5) seconds or about 8 seconds to about 12 seconds or about 3 seconds to about 7 seconds.

In some embodiments, the plasma is produced in pulse. For example, a plasma pulse period is between about 0.01 and 0.2 msec and the plasma pulse periods add up to the total plasma pulse time described above. A frequency of the pulsed plasma power can be between about 50 and 40,000 Hz or about 100 and 30,000 Hz.

In accordance with examples of the disclosure, the first reactant can comprise oxygen or a gas comprising oxygen. In accordance with further examples, the first reactant can include one or more of oxygen, H₂O, H₂O₂, NO, N₂O, NO₂ and O₃, or derivatives thereof.

Optionally, step 204 is followed by a post plasma purge step 205. During the purge step, excess reactant(s) and reaction byproducts, if any, may be removed from the reaction space/substrate surface, for example, by a purging gas pulse and/or vacuum generated by a pumping system. In some embodiments, the purging gas can be any inert gas, such as, without limitation, argon (Ar), nitrogen (N₂) and/or helium (He). A phase is generally considered to immediately follow another phase if a purge (i.e., purging gas pulse) or other reactant removal step intervenes. A flowrate of a purge gas during the purge sub step can range from about 500 sccm to about 5000 sccm or about 1000 sccm to about 4000 sccm. A time of the gas flow during the purge sub step can be relatively short to facilitate relatively rapid deposition of material. By way of examples, a time of the gas flow during this purge sub step can be greater than 0 and less than 1 second or range from about 0.1 seconds to about 0.9 seconds or about 0.3 seconds to about 0.5 seconds. In some embodiments, the purge is performed by forming a vacuum into the reaction chamber. In other words, the reactant is pumped away from the reaction chamber so that the reaction chamber is free, or substantially free from the reactant.

The steps 202-205 may be repeated in in a deposition cycle 210. Once the thickness of the first deposited layer is sufficient, such as about 1 nm, or about 2 nm, or about 3 nm, or about 4 nm, or about 5 nm, the method continues with step 206.

Steps 206-209 include performing a deposition cycle, such as a plasma-enhanced ALD deposition cycle. Each cycle can include introducing a second silicon precursor into the reaction chamber 206, an optional post precursor purge 207, providing a second active species from a reactant into the reaction chamber 208 and an optional post plasma purge 209. The silicon precursor reacts with the surface of the first deposited layer to form chemisorbed layer in the gap, and the active species from a reactant reacts with the chemisorbed layer to form a second deposited layer that eventually fills the gap. The second deposited layer may comprise silicon-containing layer. In some embodiments, the second deposited layer is selected from silicon oxide, silicon nitride, silicon oxynitride and silicon oxycarbide.

The second silicon precursor of step 207 may comprise silane amines (aminosilanes), siloxane amines and silazane amines. In some embodiments the second silicon precursor is the same as the second silicon precursor in step 202. In some embodiments, the second silicon precursor is different from the first silicon precursor in step 202. In some embodiments, the silicon precursor is selected from the list consisting of diethylaminosilane, bis(diethylamino)silane, diisopropylaminosilane, bis(dimethylamino)silane, hexaethylaminodisilane, tetraethylaminosilane, bis(tert-butylamino)silane, bis(triethylsilyl)amine, trimethylaminosilane, trimethylsilyldiethylamine, tris(dimethylamino)silane, bis(ethylmethylamino)silane, tetraethyl orthosilicate, silicon n tetrachloride, hexachlorosilane, and bis(dimethylamino)dimethylsilane.

A pulse/flow time to introduce the silicon precursor to the reaction chamber can range from, for example, about greater than 0 to less than 1 second or about 0.1 to 0.5 (e.g., 0.2) seconds, or about 1 seconds.

The active species can be formed in step 208 by using a remote plasma, such as inductively-coupled plasma. In step 208 the plasma is generated at a remote plasma unit and mainly radicals reach the surface of the substrate. A plasma power during step 208 can range from about 100 W to about 10000 W or about 150 W to about 1000 W or about 1000 W to about 10000 W. The plasma can be formed using a pulse time of and/or an on time for the plasma during step 208 can range from about 1 seconds to about 20 (e.g., 10) seconds or about 0.3 seconds to about 10 (e.g., 5) seconds or about 8 seconds to about 12 seconds or about 3 seconds to about 7 seconds.

In some embodiments, the remote plasma is produced in pulse. For example, a plasma pulse period is between about 0.01 and 0.2 msec and the plasma pulse periods add up to the total plasma on time described above.

In accordance with examples of the disclosure, the second reactant can comprise oxygen or a gas comprising oxygen. In accordance with further examples, the first reactant can include one or more of oxygen, H₂O, H₂O₂, NO, N₂O, NO₂ and O₃, or derivatives thereof.

The post precursor purge 207 and post plasma purge 209 are similar to the purge steps 203 and 205 described above. The purging sub steps under step 207 and 209 may be particularly desirable to mitigate any unwanted CVD reactions that might otherwise occur.

In some embodiments, the steps can be performed in a different order. For example, in some embodiments, steps 206-209 can be performed before steps 202-205.

Once the gap is filled by a sufficient number of cycles 211, the process ends 212.

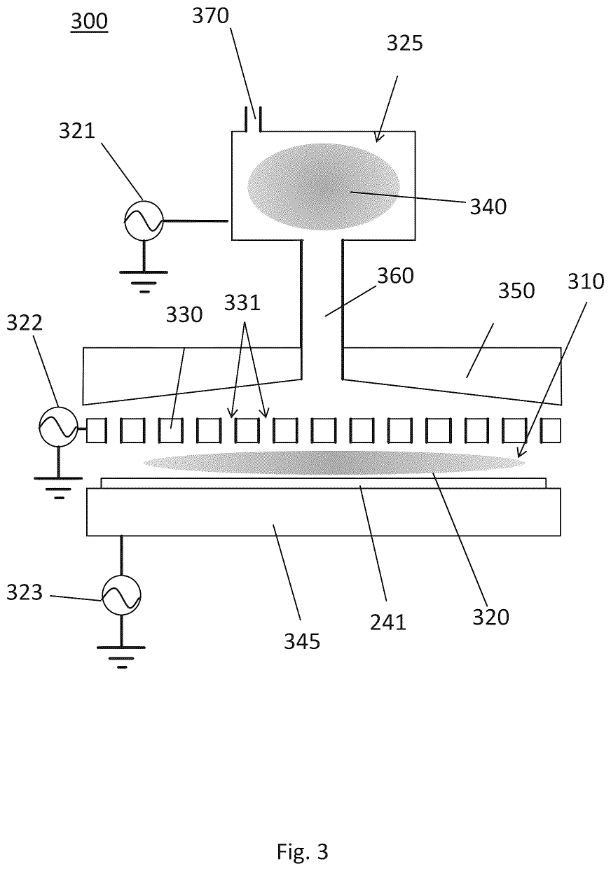

The presently provided methods may be executed in any suitable apparatus, including in an embodiment of a semiconductor processing system as shown in FIG. 3.

FIG. 3 shows a schematic representation of an embodiment of a system 300 as described herein. The system 300 comprises a reaction chamber 310 in which a direct plasma 320 is generated and which is operationally connected to a remote plasma source 325 in which plasma 340 is generated.

In particular, the direct plasma 320 is generated between a showerhead injector 330 and a substrate support 345. This is a direct plasma 320 configuration employing a capacitively-coupled plasma.

The remote plasma 340 configuration employs an inductively-coupled plasma. In particular, active species are provided from the plasma source 325 to the reaction chamber 310 via an active species duct 360, to a conical distributor 350, through holes 331 in a showerhead injector 330, to the reaction chamber 310. Thus, active species can be provided to the reaction chamber in a uniform way. In some embodiments, the showerhead injector 330 may also act as an ion trap. In other words, the ion generated by the remote plasma 340 do not pass the showerhead injector 330, instead the generated radicals pass through the holes 331 of the showerhead injector 330 into the reaction chamber 310.

In the configuration shown, the system 300 comprises three alternating current (AC) power sources: 321, 323 and 322. In some embodiments, all of the power sources are high frequency sources. In some embodiments, there are two high frequency sources, such as 321 and 323 and one low frequency source 322. During the remote plasma 340 generation, the power source 321 supplies radio frequency (RF) power to the plasma generation space ceiling, the power source 322 supplies an alternating current signal to the showerhead injector 330, and the power source 323 supplies an alternating current signal to the substrate support 345. A substrate 341 is provided on the substrate support 345. The radio frequency power can be provided, for example, at a frequency of 13.56 MHz or higher. The alternating current signal of the power source 322 can be provided, for example, at a frequency of 2 MHz or lower.

During the direct plasma 320 generation, the power source 323 supplies radio frequency (RF) power to the showerhead injector, and the power source 322 supplies an alternating current signal to the substrate support 345. The radio frequency power can be provided, for example, at a frequency of 13.56 MHz or higher, e.g. at a frequency of at least 100 kHz to at most 50 MHz, or at a frequency of at least 50 MHz to at most 100 MHz, or at a frequency of at least 100 MHz to at most 200 MHz, or at a frequency of at least 200 MHz to at most 500 MHz, or at a frequency of at least 500 MHz to at most 1000 MHz, or at a frequency of at least 1000 MHz to at most 2000 MHz. The low frequency alternating current signal can be provided, for example, at a frequency of 2 MHz or lower, such as at a frequency of at least 100 kHz to at most 200 kHz, or at a frequency of at least 200 kHz to at most 500 kHz, or at a frequency of at least 500 kHz to at most 1000 kHz, or at a frequency of at least 1000 kHz to at most 2000 kHz.

Process gas comprising precursor, reactant, or both, is provided through a gas line 370 to the plasma source 325 or the conical gas distributor 350. During the remote plasma 340 generation active species such as ions and radicals generated by the plasma 340 from the process gas are guided to the reaction chamber 310. In direct plasma 320 generation the process gas passes through holes 331 in the showerhead injector 330 to the reaction chamber 310.

Whereas the power source 321 is shown as being electrically connected to the showerhead injector, the power source 323 is shown as being electrically connected to the substrate support 345 and the power source 322 is shown as being electrically connected to the showerhead injector 330, other configurations are possible as well. For example, in some embodiments (not shown), at least one of sources can be electrically connected to the showerhead injector; or at least one of the sources can be electrically connected to the substrate support; or at least one of the sources can be electrically connected to the substrate support, and at least one power source can be electrically connected to the showerhead injector.

The system may comprise other elements not shown in the figure. Some of these elements may comprise a temperature regulator onto which a substrate can be placed and its temperature is kept constant at a given temperature. Another element not described in the figure is a circular duct with an exhaust line. The gas in the interior of the reaction chamber is exhausted through the exhaust line. Additionally, a gate valve through which a wafer may be transferred into or from the transfer chamber is omitted from this figure. The transfer chamber is also provided with an exhaust line. The system may comprise other elements not listed here.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for filling a gap with a material comprising silicon, wherein the method comprises:
providing a substrate into a reaction chamber, wherein the substrate comprises at least one gap;
providing a first reactive species generated from a capacitively-coupled plasma produced from a first reactant gas into the reaction chamber; and
executing a plurality of deposition cycles, wherein the deposition cycle comprises
providing a first silicon precursor in vapor phase into the reaction chamber; and
providing a second reactive species generated from an inductively-coupled plasma produced from a second reactant gas into the reaction chamber.

2. The method according to claim 1, further comprising providing a second silicon precursor in vapor phase into the reaction chamber before providing the first reactive species into the reaction chamber.

3. The method according to claim 1, wherein the first silicon precursor and second silicon precursor are the same.

4. The method according to claim 1, wherein the first silicon precursor and second silicon precursor are different.

5. The method according to claim 1, wherein the first silicon precursor and the second silicon precursor comprise an aminosilane.

6. The method according to claim 1, wherein the first silicon precursor and the second precursor is selected from the list consisting of diethylaminosilane, bis(diethylamino)silane, diisopropylaminosilane, bis(dimethylamino)silane, hexaethylaminodisilane, tetraethylaminosilane, bis(tert-butylamino)silane, bis(triethylsilyl)amine, trimethylaminosilane, trimethylsilyldiethylamine, tris(dimethylamino)silane, bis(ethylmethylamino)silane, tetraethyl orthosilicate, silicon tetrachloride, hexachlorosilane, and bis(dimethylamino)dimethylsilane.

7. The method according to claim 1, wherein the first reactant gas is nitrogen gas which forms an inhibition layer in a vicinity of a top of the gap, and wherein the reaction of the first silicon precursor in the vicinity of the top of the gap is at least partially inhibited by the inhibition layer.

8. The method according to claim 1, wherein the steps of providing a first reactive species into the reaction chamber, providing a first silicon precursor in vapor phase into the reaction chamber; and providing a second reactive species into the reaction chamber are performed cyclically, and wherein a ratio of a number of steps of forming first reactive species and a number of deposition cycles ranges from about 1:1 to about 1:10.

9. The method according to claim 2, wherein the first reactant gas is oxygen-containing gas.

10. The method according to claim 9, wherein the steps of providing a second silicon precursor in vapor phase into the reaction chamber and providing the first reactive species into the reaction chamber are performed cyclically to deposit a first silicon-containing layer into the gap.

11. The method according to claim 9, wherein the steps of providing a first silicon precursor in vapor phase into the reaction chamber and providing the second reactive species into the reaction chamber are performed cyclically to deposit a second silicon-containing layer into the gap.

12. The method according to claim 11, wherein the second silicon-containing layer is deposited on top of the first silicon-containing layer.

13. The method according to claim 12, wherein the deposition cycle of the second silicon-containing layer is not performed until a desired thickness of the first silicon-containing layer is deposited.

14. The method according to claim 10, wherein the first silicon-containing layer is a liner layer.

15. The method according to claim 11, wherein the second silicon-containing layer is used to fill the gap on the substrate.

16. The method according to claim 1, wherein the capacitively-coupled plasma is produced in pulse.

17. A semiconductor processing apparatus comprising:
one or more reaction chambers for accommodating a substrate comprising a gap;
a first source for a first reactant in gas communication via a first valve with one of the reaction chambers;
a second source for a second reactant in gas communication via a second valve with one of the reaction chambers;
a third source for a first silicon precursor in gas communication via a third valve with one of the reaction chambers;
a capacitively-coupled plasma source connected to at least one of the reaction chambers;
an inductively-coupled plasma source connected to at least one of the reaction chambers; and
a controller operably connected to the first, second, and third gas valves and configured and programmed to control:
providing a first reactive species generated from a capacitively-coupled plasma produced from a first reactant gas into the reaction chamber;
executing a plurality of deposition cycles, wherein the deposition cycle comprises
providing a first silicon precursor in vapor phase into the reaction chamber; and
providing a second reactive species generated from an inductively-coupled plasma produced from a second reactant gas into the reaction chamber.

18. The semiconductor processing apparatus according to claim 17, further comprising a fourth source for a second silicon precursor in gas communication via a fourth valve with one of the reaction chambers, and wherein the controller is further operably connected to the fourth gas valve and configured and programmed to control providing a second silicon precursor in vapor phase into the reaction chamber before providing the first reactive species into the reaction chamber.

19. The semiconductor processing apparatus according to claim 17, wherein the capacitively-coupled plasma source, and the inductively-coupled plasma source are connected to the same reaction chamber.

20. The semiconductor processing apparatus according to claim 19, wherein the capacitively-coupled plasma source is connected to a substrate support supporting the substrate in the reaction chamber.
